(19) United States
(12) Patent Application Publication
(10) Pub. No.: US 2026/0235955 A1
(43) Pub. Date: Aug. 13, 2026

(54) POSITIVE-TYPE MULTILAYER MOLECULAR FILM PHOTORESIST HAVING MOLECULAR LINE STRUCTURE

(71) Applicant: Samsung Electronics Co., Ltd., Suwon-si, Gyeonggi-do (KR)

(72) Inventors: Myung Mo Sung, Suwon-si, Gyeonggi-do (KR); Hyeon Seok Ji, Suwon-si, Gyeonggi-do (KR); Jae Hyuk Lee, Suwon-si, Gyeonggi-do (KR); Yeong Eun Bak, Suwon-si, Gyeonggi-do (KR); Jinho Ahn, Suwon-si, Gyeonggi-do (KR)

(73) Assignee: Samsung Electronics Co., Ltd., Suwon-si, Gyeonggi-do (KR)

(21) Appl. No.: 19/155,202

(22) PCT Filed: Feb. 8, 2024
(86) PCT No.: PCT/KR2024/001930

§ 371 Date: Aug. 8, 2025

(30) Foreign Application Priority Data
Feb. 10, 2023 (KR) 10-2023-0017923
Feb. 8, 2024 (KR) 10-2024-0019373

(51) Int. Cl. G03F 7/09; G03F 7/004; G03F 7/20

(52) U.S. Cl. CPC G03F 7/094; G03F 7/0042; G03F 7/2004; G03F 7/203

(57) ABSTRACT

Provided is a multilayer molecular film photoresist. The multilayer molecular film photoresist includes a plurality of molecular lines arranged in a horizontal direction and each extending in an upward direction with respect to a substrate, each molecular line including monomolecules linearly connected to each other, and the monomolecules including multiple inorganic monomolecules including metal atoms and an organic monomolecule connected between at least some inorganic monomolecules from among the inorganic monomolecules. The organic monomolecule included in one of the molecular lines is cross-linked with an inorganic monomolecule in another adjacent molecular line. The cross-linking is broken by irradiation of radiation.

### TECHNICAL FIELD

The present disclosure relates to a photoresist, and more particularly, to a photoresist for EUV.

### BACKGROUND ART

Research on photoresists has been continuously conducted, and in particular, methods of preparing liquid-state photosensitive solutions and then depositing the photosensitive solutions on substrates through spin-coating have been most actively studied. As such typical photoresists, chemically amplified resists (CARs) including polymeric resins, photo-acid generators (PAGs), and bases (that is, quenchers) are mainly used.

Recently, in the semiconductor industry, extreme ultraviolet (EUV) photolithography that uses EUV light sources capable of forming ultra-fine patterns with sizes of 10 nm or less has been introduced.

However, EUV has a low photon density that is 1/14 that of deep UV (DUV) with a wavelength of 193 nm, and thus, may cause stochastic failure, specifically, photon shot noise. For example, in the case of the CARs, due to low photon densities, there is a low probability of PAGs reacting, and thus, shot noise may occur. In addition, it is known that, in the case of CARs, because polymeric resins have large particle sizes of 4 nm or more, there is a drawback of exhibiting relatively large line edge roughness.

### DISCLOSURE OF INVENTION

### Technical Problem

The present disclosure provides a photoresist having excellent photon absorption and low line edge roughness and a method of preparing the photoresist.

The present disclosure is not limited to the above aspects, and the above and other aspects of the present disclosure will be clearly understood by those of ordinary skill in the art from the following description.

### Solution to Problem

An embodiment of the present disclosure provides a multilayer molecular film photoresist. The multilayer molecular film photoresist includes a plurality of molecular lines arranged in a horizontal direction and each extending in an upward direction with respect to a substrate, each molecular line including monomolecules linearly connected to each other, and the monomolecules including multiple inorganic monomolecules including metal atoms and an organic monomolecule connected between at least some inorganic monomolecules from among the inorganic monomolecules. The organic monomolecule included in one of the molecular lines is cross-linked with an inorganic monomolecule in another adjacent molecular line. The cross-linking is broken by irradiation of radiation.

The metal atoms included in the inorganic monomolecules may be Te.

The inorganic monomolecules and the organic monomolecule, which are located within the molecular lines, may be connected to each other by a bond that is included in one thereof and selected from the group consisting of —O—, —S—, —Se—, —NR— (where R is H or CH₃) and —PR— (where R is H or CH₃).

The organic monomolecule may include, as a body, an aromatic or non-aromatic ring or a linear or branched alkylene group, —Z₅X_{c}—*′ being bonded to a side portion of the body, wherein Z₅ may be a direct bond or a C1 to C5 substituted or unsubstituted and linear or branched alkylene group, X_{c} may be O, S, Se, NR (where R is H or CH₃), or PR (where R is H or CH₃), and *′ may be a cross-link with an inorganic monomolecule in another adjacent molecular line.

The organic monomolecule may be represented by Formula 3.

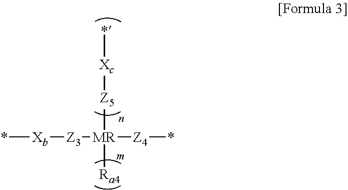

In Formula 3, MR, which is a body of the organic monomolecule, may be an aromatic or non-aromatic ring or a linear or branched alkylene group, one of the * may be a bond with a lower inorganic monomolecule in the same molecular line, the other * may be a bond with an upper inorganic monomolecule in the same molecular line, and *′ may be a cross-link with an inorganic monomolecule in another adjacent molecular line. X_{b} and X_{c} may each independently be O, S, Se, NR (where R is H or CH₃), or PR (where R is H or CH₃), Z₃, Z₄, and Z₅ may each independently be a direct bond or a C1 to C5 substituted or unsubstituted and linear or branched alkylene group, Rₐ₄ may be hydrogen or a C1 to C2 alkyl group, n may be 1 to 2, and m may be 0 to 1. In an example, MR may be a C2 to C6 linear alkylene group, Z₃, Z₄, and Z₅ may be direct bonds, X_{b} may be O, X_{c} may be S, n may be 1, and m may be 0.

The inorganic monomolecules may be represented by Formula 2.

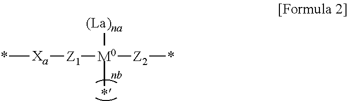

In Formula 2, one of the * may be a bond with a lower monomolecule in the same molecular line, the other * may be a bond with an upper monomolecule in the same molecular line, and *′ may be a cross-link with an organic monomolecule in another adjacent molecular line. M⁰ may be Te. Xₐ may be O, S, Se, NR (where R is H or CH₃), or PR (where R is H or CH₃). Z₁ and Z₂ may each independently be a direct bond, a C1 to C20 substituted or unsubstituted linear or branched alkylene group, a C1 to C20 substituted or unsubstituted linear or branched alkylene oxide, a C1 to C20 substituted or unsubstituted linear or branched alkyleneamino, a C1 to C20 substituted or unsubstituted linear or branched alkylenesilylamino, a C1 to C20 substituted or unsubstituted linear or branched alkylenethio, a C1 to C20 substituted or unsubstituted linear or branched alkyleneseleno, or a C1 to C20 substituted or unsubstituted linear or branched alkylenephosphino. Lₐ may be a halogen group, a C1 to C5 alkyl group, a C1 to C5 alkylenesilylamino group, a C1 to C5 alkoxy group, a C1 to C5 alkylthio group, a C1 to C5 alkylseleno group, or a C1 to C5 alkylamino group, or a C1 to C5 alkylphosphino group. na may be an integer of 0 to 3. nb may be an integer of 1 to 2. In an example, Xₐ may be S, Z₁ and Z₂ may be direct bonds, and nb may be 1.

The radiation may be an e-beam or EUV. There may be a Van der Waals interaction between the organic monomolecules within molecular lines adjacent to each other in the horizontal direction.

An embodiment of the present disclosure provides a method of fabricating a multilayer molecular film photoresist pattern. First, a multilayer molecular film photoresist is provided, wherein the multilayer molecular film photoresist includes a plurality of molecular lines arranged in a horizontal direction and each extending in an upward direction with respect to a substrate, each molecular line includes monomolecules linearly connected to each other, the monomolecules includes multiple inorganic monomolecules including metal atoms and an organic monomolecule connected between at least some inorganic monomolecules from among the inorganic monomolecules, and an organic monomolecule included in one of the molecular lines is cross-linked with an inorganic monomolecule in another adjacent molecular line. A region of the multilayer molecular film photoresist is irradiated with radiation that is an e-beam or EUV. Here, the cross-linking in the region irradiated with the radiation gets broken. The region, which is exposed to the radiation, of the multilayer molecular film photoresist removed by development thereof.

### Advantageous Effects of Invention

A multilayer molecular film photoresist according to an embodiment of the present disclosure may allow molecular lines thereof rather than particles thereof to be separated from each other when undergoing light-exposure and development. Therefore, the multilayer molecular film photoresist may have extremely low line edge roughness (LER), which refers to pattern side roughness, and may also have significantly improved resolution.

In addition, the multilayer molecular film photoresist of the present disclosure may allow a bond in a light-exposed region thereof to be broken, and thus, may implement a positive-type photoresist pattern.

### BRIEF DESCRIPTION OF DRAWINGS

FIG. 1 is a schematic diagram illustrating a multilayer molecular film photoresist having a vertical molecular line structure, according to an embodiment of the present disclosure.

FIG. 2 is a schematic diagram more specifically illustrating a multilayer molecular film photoresist having a vertical molecular line structure, according to an embodiment of the present disclosure.

FIG. 3 is a schematic diagram illustrating a device for preparing a multilayer molecular film photoresist having a vertical molecular line structure, according to an embodiment of the present disclosure.

FIGS. 4 to 7 are schematic diagrams sequentially illustrating a photolithography method according to an embodiment of the present disclosure.

FIG. 8 is a schematic diagram illustrating an EUV irradiation form and a dose condition, and FIG. 9 shows optical photographs of photoresist patterns obtained after an EUV pattern shown in FIG. 8 is irradiated onto a photoresist according to a Preparation Example.

### MODE FOR THE INVENTION

As used herein, the term “metal” may be a concept including all metals and may include, for example, a transition metal, a post-transition metal, or a semimetal.

Herein, radiation may include, for example, extreme ultraviolet (EUV) or an electron beam (e-beam). However, the present disclosure is not limited thereto in some cases.

As used herein, the term “monomolecule” refers to a molecule that is not a polymer and may refer to, for example, a small molecule, specifically, a molecule having 100 or less atoms, specifically, 30 or less atoms.

Herein, when molecules or functional groups are referred to as being “connected by a bond”, the molecules or functional groups may be directly connected to each other or may be indirectly connected to each other via another or other molecule(s) or functional group(s) arranged therebetween.

As used herein, the expression “carbon number X (that is, CX) to carbon number Y (that is, CY)” should be construed as including all cases of having carbon atoms corresponding to all integers between X and Y. For example, the expression “C1 to C10” should be construed as including all of C1, C2, C3, C4, C5, C6, C7, C8, C9, and C10.

As used herein, the expression “X to Y” should be construed as including all integers between X and Y. For example, the expression “1 to 10” should be construed as including all of 1, 2, 3, 4, 5, 6, 7, 8, 9, and 10.

As used herein, the term “aromatic ring” may refer to a 5- to 12-membered, specifically, 5- to 6-membered aromatic ring and may have a homocyclic structure in which all constituent members are carbon atoms, or a heterocyclic structure in which some of constituent members are substituted with heterogeneous elements.

When the term “alkylene group” or “alkyl group” is used herein, all elements constituting a main chain thereof may be carbon, or some carbon atoms of the main chain may be substituted with O, S, N, C═O, or Si. A substitute element is not limited thereto.

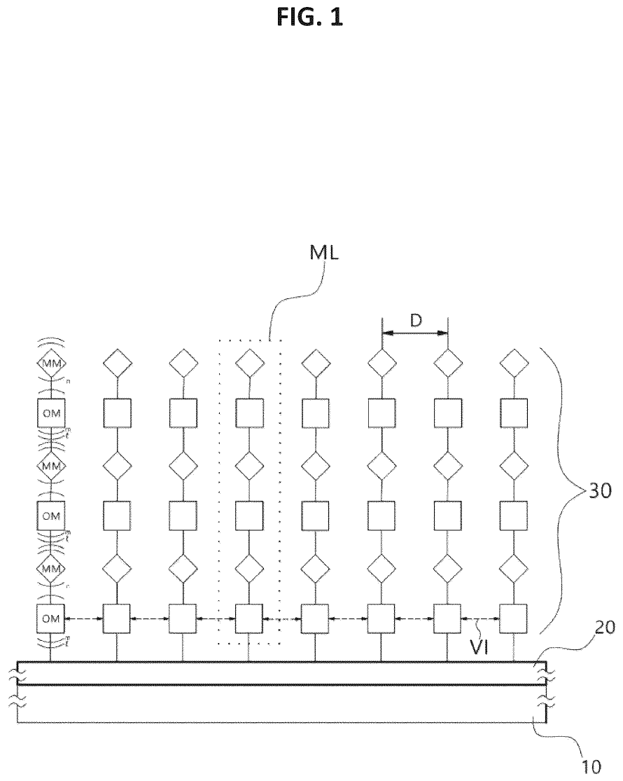

FIG. 1 is a schematic diagram illustrating a multilayer molecular film photoresist having a vertical molecular line structure, according to an embodiment of the present disclosure.

Referring to FIG. 1, a substrate 10 may be provided. The substrate may include a semiconductor substrate, a glass substrate, or a bare substrate that is a flexible substrate. For example, the flexible substrate may include a polymer substrate. At least one device (not shown), such as a transistor, a memory, a diode, a solar cell, an optical device, a biometric sensor, a nano-electromechanical system (NEMS), a micro-electromechanical system (MEMS), a nano-device, or a chemical sensor, may be formed on the substrate. The device may include an organic electronic device, such as an organic light-emitting diode or an organic solar cell. As such, in the present embodiment, the substrate 10 may include the bare substrate or may include the bare substrate on which the device is formed.

An etch-target layer 20 may be formed on the substrate 10. The etch-target layer 20 is a layer in which a pattern is to be formed by forming a photoresist pattern on the layer and then etching the layer by using the photoresist pattern as an etch mask, and may include various materials used in a semiconductor process. For example, the etch-target layer 20 may include a metal film, a semiconductor film, an insulating film, or a composite film including one thereof. The metal film is for forming a wiring line and may include aluminum, tungsten, titanium, or a composite film including one thereof. The semiconductor film may include a silicon film, for example, monocrystalline silicon, polysilicon, an amorphous silicon film, or a composite film including one thereof. The insulating film may include an inorganic insulating film, such as a silicon oxide film or a silicon nitride film; an organic insulating film, such as an amorphous carbon layer; or a composite film including one thereof. For example, the etch-target layer 20 may include the bare substrate.

The etch-target layer 20 may include a surface functional group, for example, a hydroxyl group, a thiol group, an amine group, or a phosphine group or may be surface-treated so as to include the surface functional group.

A multilayer molecular film photoresist 30 having a molecular line structure may be formed on the etch-target layer 20.

The multilayered molecular film photoresist 30 may include a plurality of molecular lines (that is, ML) arranged in a horizontal direction, each of the plurality of molecular lines (that is, ML) including inorganic monomolecules (that is, MM) that are directly or indirectly connected to each other by a bond. As used herein, the term “molecular line” may be defined as a backbone, a molecular chain, or a main chain formed of monomolecules connected to each other by a bond. Here, the expression “indirectly connected to each other” may mean that another monomolecule, for example, an organic monomolecule (that is, OM) described below, or a functional group is connected between the inorganic monomolecules (that is, MM). The bond may include a covalent bond or a coordinate bond. In an example, the molecular lines (that is, ML) may each extend in an upward direction, for example, a vertical direction, with respect to the substrate 10, and the horizontal direction may be a direction that is substantially parallel to a surface of the substrate 10.

In the present embodiment, because the multilayered molecular film photoresist 30 is formed by atomic layer deposition or molecular layer deposition, almost all molecular lines (that is, ML) in the multilayered molecular film photoresist 30 may have a substantially identical stack structure. As a result, the molecular lines (that is, ML) in the multilayer molecular film photoresist 30 may have, in the horizontal direction, a substantially identical inorganic monomolecular layer and a substantially identical organic monomolecular layer. In other words, inorganic monomolecules respectively in the molecular lines may be arranged substantially equally in the horizontal direction to constitute an inorganic monomolecular layer, and organic monomolecules respectively in the molecular lines may be arranged substantially equally in the horizontal direction to constitute an organic monomolecular layer.

The multilayer molecular film photoresist 30 may include an organic-inorganic multilayered molecular film photoresist. Specifically, the multilayer molecular film photoresist 30 may refer to a multilayer molecular film photoresist in which an organic monomolecule (that is, OM) is arranged and bonded between at least some inorganic monomolecules (that is, MM) included in each molecular line (that is, ML). In this case, the multilayer molecular film photoresist 30 may include a plurality of molecular lines (that is, ML), which are arranged in the horizontal direction, and in each of which an organic monomolecule (that is, OM) and an inorganic monomolecule (that is, MM) are connected to each other by a bond, wherein there is a Van der Waals interaction (that is, VI) between organic monomolecules (that is, OM) within adjacent molecular lines (that is, ML) from among the molecular lines (that is, ML). Here, the Van der Waals interaction (that is, VI) may allow a pattern not to collapse by stabilizing the molecular lines (that is, ML) adjacent to each other in the horizontal direction, even when the pattern has a high aspect ratio. The Van der Waals interaction may include, for example, a Van der Waals interaction between alkyl groups or a π-π bond between aromatic groups.

The multilayer molecular film photoresist 30 may have a layer configuration represent by Formula 1 shown below.

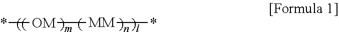

In Formula 1, one of the * may be a bond with a functional group in a lower layer or a functional group in a lower monomolecule, and the other * may be a bond with a functional group in an upper layer or a functional group in an upper monomolecule. Here, the bond may be, for example, a covalent bond. In Formula 1, m may be 0 to 10, n may be 1 to 10, and l may be 1 to 10000, specifically, 20 to 1000, more specifically, 25 to 100. Specifically, m may be 1 to 2, for example, m may be 1. In addition, n may be 1 to 2, for example, n may be 1. Formula 1 may represent both the case where OM and MM are sequentially stacked in the stated order on the lower layer and the case where MM and OM are sequentially stacked in the stated order on the lower layer.

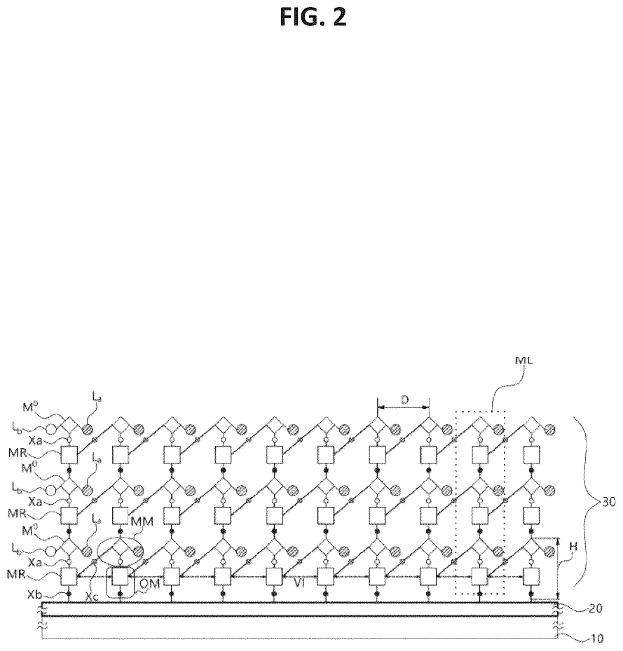

FIG. 2 is a schematic diagram more specifically illustrating a multilayer molecular film photoresist having a vertical molecular line structure, according to an embodiment of the present disclosure. FIG. 2 illustrates an example of a multilayer molecular film photoresist when all of n, m, and l in FIG. 1 are 1, for convenience of description.

Referring together to FIGS. 1 and 2, the multilayer molecular film photoresist 30 may have a layer configuration as in Formula 1.

Here, OM is an organic monomolecule, and specifically, OM may include, as a body, an aromatic or non-aromatic ring or a linear or branched alkylene group. The alkylene group may extend in a direction substantially identical to the extension direction of the molecular line (that is, ML), and a major axis of the ring may be in a direction substantially identical to the extension direction of the molecular line (that is, ML). OM may be boned to a lower layer or a lower inorganic monomolecule (that is, MM) via O, S, Se, NR (where R is H or CH₃), or PR (where R is H or CH₃) that is directly or indirectly connected to a lower portion of the body. In addition, OM may be boned to an upper layer or an upper inorganic monomolecule (that is, MM) via O, S, Se, NR (where R is H or CH₃), or PR (where R is H or CH₃) that is directly or indirectly connected to an upper portion of the body.

For example, OM may be an organic monomolecule represented by Formula 3 shown below.

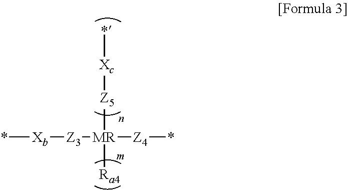

In Formula 3, MR, which is a body of the organic monomolecule, may be an aromatic or non-aromatic ring or a linear or branched alkylene group. The alkylene group may extend in a direction substantially identical to the extension direction of the molecular line (that is, ML), and a major axis of the ring may be in a direction substantially identical to the extension direction of the molecular line (that is, ML).

One of the * may be a bond with a functional group in a lower layer or a lower inorganic monomolecule, and the other * may be a bond with a functional group in an upper layer or an upper inorganic monomolecule. Here, the bond may be, for example, a covalent bond. X_{b} may be O, S, Se, NR (where R is H or CH₃), or PR (where R is H or CH₃). In an example, X_{b} may be O.

*′ may be a cross-link with an inorganic monomolecule in another adjacent molecular line. X_{c} may be O, S, Se, NR (where R is H or CH₃), or PR (where R is H or CH₃). In an example, X_{c} has lower reactivity than X_{b}, and specifically, may be S. n may be 1 to 2.

Rₐ₄ may be hydrogen or a C1 to C2 alkyl group. m may be 0 to 1.

—Z₅X_{c}—*′ and —Rₐ₄, which are cross-linkable functional groups bonded to a side portion of MR, may be bonded to the same member in MR or may be bonded to different members in MR. When —Z₅X_{c}—*′ and —Rₐ₄ are bonded to the same member, the numbers thereof may be limited within the number of covalent bonds allowed for the member.

Z₃, Z₄, and Z₅ may each independently be a direct bond or a C1 to C5 substituted or unsubstituted and linear or branched alkylene group.

In an example, MR in Formula 3 may be a substituted or unsubstituted aromatic or non-aromatic ring. The non-aromatic ring may also be referred to as a cyclic alkylene. Here, the term “substituted” may mean that hydrogen of the aromatic ring is substituted with various functional groups. When MR is an aromatic ring, Z₃, Z₄, and Z₅ may each independently be a C1 to C5 substituted or unsubstituted and linear or branched alkylene group. Here, the term “substituted” may mean that hydrogen of the alkylene group is substituted with OH, SH, SeH, NR₂ (where R is each independently H or CH₃), or PR₂ (where R is each independently H or CH₃).

In another example, MR in Formula 3 may be a C1 to C18, specifically, C2 to C6, substituted or unsubstituted and linear or branched alkylene group. In an example, MR may be a C2 to C6 linear alkylene group. The term “substituted” may mean that hydrogen of the alkylene group is substituted, due to radiation, with a cross-linkable functional group, for example, a functional group including a vinyl group, or with OH, SH, SeH, NR₂ (where R are each independently H or CH₃), or PR₂ (where R are each independently H or CH₃). In addition, as defined above, in the alkylene group, all elements constituting a main chain thereof may be carbon, or some carbon atoms of the main chain may be substituted with O, S, N, C═O, or Si, but a substitute element is not limited thereto. When MR is a linear or branched alkylene group, Z₃ and Z₄ may be direct bonds, and Z₅ may each independently be a direct bond or a C1 to C5 substituted or unsubstituted and linear or branched alkylene group. —Z₅X_{c}—*′ and —Rₐ₄, which are functional groups bonded to a side portion of MR, may be bonded to carbon in MR or to N or Si introduced in substitution for carbon. When —Z₅X_{c}—*′ and —Rₐ₄ are bonded to the same member, the numbers thereof may be limited within the number of covalent bonds allowed for the member.

MM may be an inorganic monomolecule including a metal element, specifically, may be an organic-inorganic monomolecule. MM may be, for example, an organic-inorganic monomolecule including Te.

Specifically, a central metal (that is, M⁰) of MM may be bonded to a lower layer or an underlying organic monomolecule (that is, OM) directly or indirectly via O, S, Se, NR (where R is H or CH₃), or PR (where R is H or CH₃). MM may be an inorganic monomolecule represented by Formula 2 shown below.

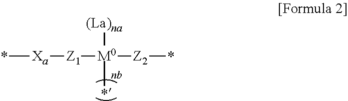

In Formula 2, one of the * may be a bond with a functional group in a lower layer or with a lower monomolecule, specifically, a lower organic monomolecule, and the other * may be a bond with a functional group in an upper layer or with an upper monomolecule, specifically, an upper organic monomolecule. Here, the bond may be, for example, a covalent bond. *′ may be a bond with an organic monomolecule in another adjacent molecular line. *′ may be present as many as nb. nb may be an integer of 1 to 2.

M⁰ may be Te.

Z₁ and Z₂ may each independently be a C1 to C20 substituted or unsubstituted linear or branched alkylene group, a C1 to C20 substituted or unsubstituted linear or branched alkylene oxide, a C1 to C20 substituted or unsubstituted linear or branched alkyleneamino, a C1 to C20 substituted or unsubstituted linear or branched alkylenesilylamino, a C1 to C20 substituted or unsubstituted linear or branched alkylenethio, a C1 to C20 substituted or unsubstituted linear or branched alkyleneseleno, or a C1 to C20 substituted or unsubstituted linear or branched alkylenephosphino. Xₐ may be O, S, Se, NR (where R is H or CH₃), or PR (where R is H or CH₃).

Lₐ is a functional group or a ligand bonded to M⁰, and Lₐ may be a halogen group (for example, Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. Here, C1 to C5 alkyl groups may be substituted or unsubstituted linear or branched alkyl groups.

The sum of na and nb may be equal to or less than a value obtained by subtracting 2, which is the number of bonds with upper and lower functional groups (that is, Z₁ and Z₂), from a maximum coordination number caused by M⁰. Here, the maximum coordination number may refer to a maximum oxidation number of M⁰. For example, na may be an integer of 0 to 3.

When na in Formula 2 is 2 or more, Lₐ may each independently be selected from the examples set forth above. In an example, when na is 2 or more, two among Lₐ may be combined with M⁰ attached thereto, and thus, may form a heterocyclyl or a heteroaryl. Respective bonds between Z₁, Z₂, and Lₐ, and M⁰ as well as *′ may each independently be a covalent bond or a coordinate bond.

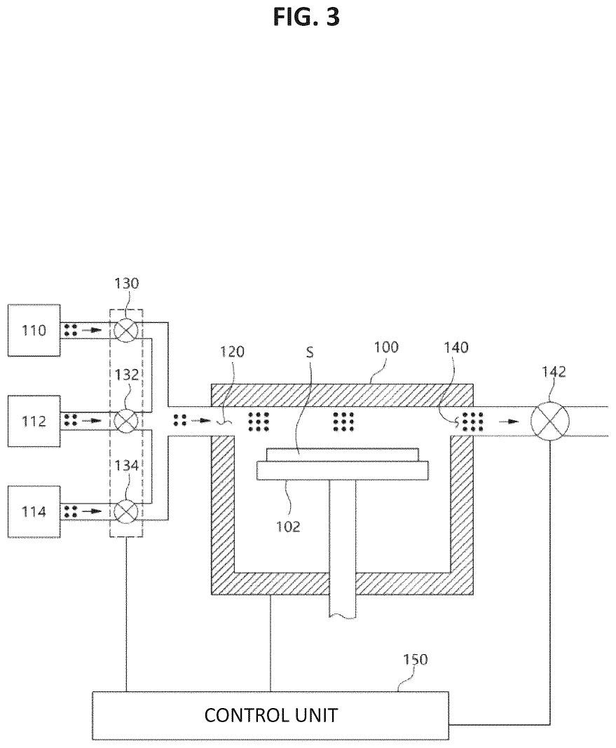

FIG. 3 is a schematic diagram illustrating a device for preparing a multilayer molecular film photoresist having a vertical molecular line structure, according to an embodiment of the present disclosure.

Referring together to FIGS. 2 and 3, a substrate S may be loaded on a stage 102 in a chamber 100 that includes a gas inlet port 120 and a gas outlet port 140. The substrate S may include the substrate 10 on which the etch-target layer 20 is formed, as described with reference to FIG. 1.

Before the substrate S is loaded, the chamber 100 may be heated to and maintained at a deposition temperature by a control unit 150. The deposition temperature may be 20° C. to 250° C., 50° C. to 200° C., 80° C. to 150° C., 90° C. to 140° C., or 100° C. to 130° C. The gas outlet port 140 may be connected to a vacuum pump.

First, all gas inlet valves (that is, 130, 132, and 134) connected to the gas inlet port 120 may be closed, and a gas outlet valve 142 connected to the gas outlet port 140 may be opened, thereby making the inside of the chamber 100 into a vacuum state.

Next, the multilayer molecular film photoresist 30 may be formed by performing a cycle that includes forming an inorganic monomolecular layer (that is, MM) and forming an organic monomolecular layer (that is, OM). Herein, although a unit cycle of forming the organic monomolecular layer (that is, OM) and then forming the inorganic monomolecular layer (that is, MM) is described, this also includes forming the inorganic monomolecular layer (that is, MM) and then forming the organic monomolecular layer (that is, OM) when the unit cycle is performed.

In the forming of the organic monomolecular layer (that is, OM), an organic monomolecular layer unit cycle may be performed, the organic monomolecular layer unit cycle including an organic precursor dosing operation for chemically bonding an organic precursor to a lower layer in a self-assembly manner by dosing the organic precursor and a purge operation for purging the unreacted organic precursor and a reaction product by supplying a purge gas.

The organic precursor may include an aromatic or nonaromatic ring or a linear or branched alkylene group as a body, ORₐ₁, SRₐ₁, SeRₐ₁, NRRₐ₁ (where R is H or CH₃), or PRRₐ₁ (where R is H or CH₃) directly or indirectly bonded to one side of the body, ORₐ₂, SRₐ₂, SeRₐ₂, NRRₐ₂ (where R is H or CH₃), or PRRₐ₂ (where R is H or CH₃) directly or indirectly bonded to the other side of the body, and ORₐ₃, SRₐ₃, SeRₐ₃, NRRₐ₃ (where R is H or CH₃), or PRRₐ₃ (where R is H or CH₃) directly or indirectly bonded to a side portion of the body. Here, Rₐ₁, Rₐ₂, and Rₐ₃ may each independently be hydrogen or a C1 to C2 alkyl group.

In an example, the organic precursor may be represented by Formula 4 shown below.

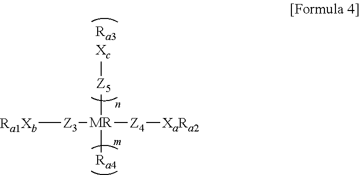

In Formula 4, Rₐ₁, Rₐ₂, Rₐ₃, and Rₐ₄ may each independently be hydrogen or a C1 to C2 alkyl group, and Xₐ and X_{c} may each independently be O, S, Se, NR (where R is H or CH₃), or PR (where R is H or CH₃). For example, X_{b} may be O, Xₐ may be S, and X_{c} may be S. Z₃, Z₄, Z₅, MR, n, and m are the same as defined in Formula 3. Here, —Z₅X_{c}Rₐ₃ may be referred to as a cross-linkable functional group.

Specific examples of the organic precursor may be as follows.

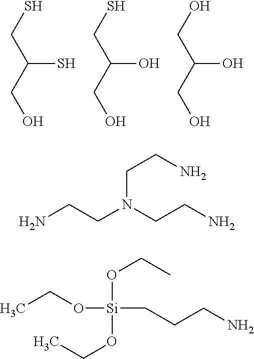

In the organic precursor dosing operation, a reaction according to Reaction Formula 1 shown below may occur.

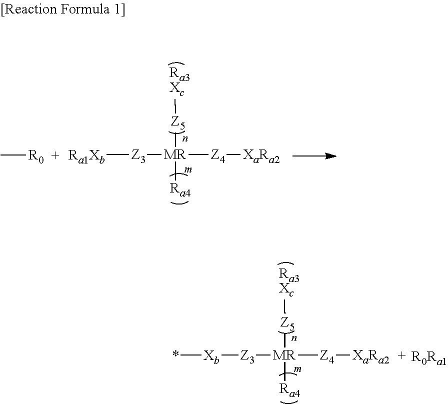

In Reaction Formula 1, R₀ is a functional group on a surface of a lower layer or a surface functional group (that is, R_{b2} in Reaction Formula 2 shown below) of an inorganic precursor layer described below, and R₀ may be hydrogen, a hydroxyl group, a thiol group, an amine group, a phosphine group, a C1 to C5 alkyl group, a C1 to C5 alkoxy group, a C1 to C5 alkylthio group, a C1 to C5 alkylseleno group, a C1 to C5 alkylamine group, or a C1 to C5 alkylphosphino group. Rₐ₁X_{b}—Z₃-MR(—Z₄—XₐRₐ₂)(—Z₅—X_{c}Rₐ₃)ₙ(—Rₐ₄)ₘ is an organic precursor, and respective functional groups thereof are the same as defined in Formula 4. When X_{b} and Xₐ are different from each other, a functional group having higher reactivity may be bonded to the surface functional group of the lower layer. For example, when X_{b} and Xₐ are respectively O and S, O may be bonded to the surface functional group of the lower layer.

Referring to Reaction Formula 1, the organic precursor may react with the functional group on the surface of the lower layer and thus be self-assembled on the lower layer. During this process, R₀Rₐ₁ may be generated as a reaction by-product. Next, in the purge operation, the remaining excess organic precursor and the reaction by-product may be purged.

In the organic precursor dosing operation, while an organic precursor control valve 134 is opened and the gas outlet valve 142 is closed, the organic precursor may be supplied from an organic precursor storage unit 114 to the inside of the chamber 100 (an organic precursor supply operation). The organic precursor may be stored in a solid state, a liquid state, or a gaseous state in the organic precursor storage unit 114. The organic precursor storage unit 114 may be heated, and the organic precursor may be supplied at a certain vapor pressure into the chamber 100. In an embodiment, the organic precursor may be supplied without a carrier gas. In other words, the organic precursor alone may be supplied into the chamber 100.

Because the organic precursor is supplied while the gas outlet valve 142 is closed, the organic precursor may be accumulated in the chamber 100 to increase the pressure in the chamber 100. The organic precursor may be supplied such that the pressure of the chamber 100 reaches a reaction pressure (the organic precursor supply operation). Here, the reaction pressure is a pressure of the organic precursor alone in the chamber 100 and may be tens of mTorr to 10 Torr, specifically, 50 mTorr to 10 Torr, 100 mTorr to 6 Torr, 130 mTorr to 3 Torr, or 150 mTorr to 1 Torr. In general, a precursor is dosed together with a carrier gas into a chamber, and in this case, considering that the partial pressure of the precursor is about 1 mTorr to about 10 mTorr, the case where the pressure of the organic precursor alone in the chamber 100 is 50 mTorr or more may mean that the organic precursor is pressurized.

When the pressure of the chamber 100 reaches the reaction pressure, the organic precursor control valve 134 may be closed, and while the organic precursor control valve 134 is closed, the chamber may be sealed for a certain period of time (an organic precursor exposure operation). The organic precursor supply operation and the organic precursor exposure operation may be referred to as the organic precursor dosing operation. However, the organic precursor exposure operation may be omitted in some cases. In the organic precursor dosing operation, the reaction according to Reaction Formula 1 may occur.

Next, the chamber 100 may be purged (an organic precursor purge operation). Specifically, a purge gas in a purge gas storage unit 112 may flow onto a surface of the substrate by opening a purge gas control valve 132 and the gas outlet valve 142, thereby removing the unreacted excess organic precursor and the reaction by-product. Here, the purge gas is an inert gas, and the inert gas may include, for example, argon (Ar), nitrogen (N₂), or a combination thereof.

In the forming of the inorganic monomolecular layer (that is, MM), a unit cycle may be performed, the unit cycle including a metal precursor dosing operation for chemically bonding a metal precursor to the lower layer in a self-assembly manner by dosing the metal precursor; and a purge operation for purging the unreacted metal precursor and a reaction product by supplying a purge gas.

The metal precursor may include an organic-inorganic monomolecule including at least two organic functional groups or ligands. The metal precursor may be represented by Formula 5 shown below.

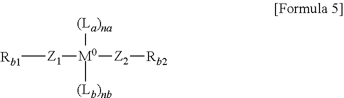

In Formula 5, R_{b1} and R_{b2} may each independently be a halogen group (for example, Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. Here, C1 to C5 alkyl groups may each be a substituted or unsubstituted linear or branched alkyl group.

Lₐ and L_{b} are functional groups bonded to M⁰, and the sum of na and nb, which are respective numbers of these functional groups, may be equal to or less than a value obtained by subtracting 2, which is the number of bonds with upper and lower functional groups (that is, Z₁ and Z₂), from the maximum coordination number caused by M⁰. For example, the sum of na and nb may be an integer of 0 to 4. Lₐ and L_{b} may each independently be a halogen group (for example, C1, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. Here, C1 to C5 alkyl groups may be substituted or unsubstituted linear or branched alkyl groups. In addition, when na and/or nb is 2 or more, Lₐ and/or L_{b} may each independently be selected from the examples set forth above. In an example, when the sum of na and nb is 2 or more, two among Lₐ and L_{b} may be combined with M⁰ attached thereto, and thus, may form a heterocyclyl or a heteroaryl.

Z₁, Z₂, and M⁰ are the same as defined in Formula 2. In addition, in some cases, two of R_{b1}, R_{b2}, Lₐ, and L_{b} may be combined with M⁰ directly or indirectly bonded thereto, and thus, may form a heterocyclyl or a heteroaryl. In an example, at least one of R_{b1} and R_{b2} may be coordinately bonded to M⁰. Respective bonds between Z₁, Z₂, Lₐ, or L_{b} and M⁰ may each independently be a covalent bond or a coordinate bond.

For example, Z₁ and Z₂ may be direct bonds, and Lₐ, L_{b}, R_{b1}, and R_{b2} may be functional groups identical to each other. As another example, Z₁ and Z₂ may be direct bonds, Lₐ and L_{b} may be functional groups identical to each other, and R_{b1} and R_{b2} may be functional groups identical to each other, wherein Lₐ and R_{b1} may be different from each other.

Specific examples of the metal precursor may be as follows.

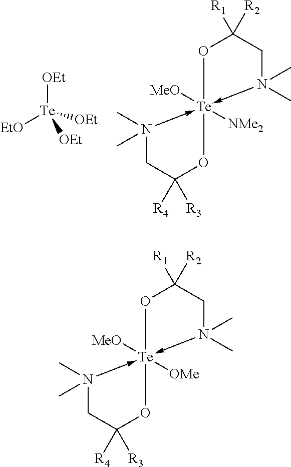

In the metal precursor dosing operation, a reaction according to Reaction Formula 2 shown below may occur. PGP

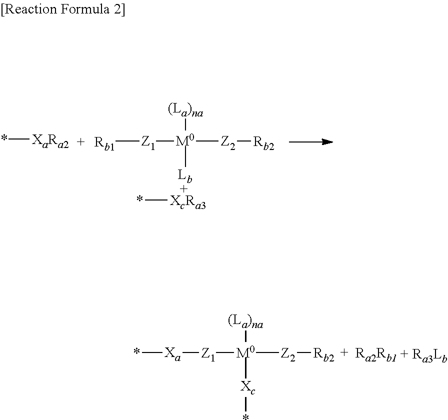

In Reaction Formula 2, *—XₐRₐ₂ is a surface functional group of a lower layer, specifically, a surface functional group of the organic molecular layer (that is, OM), and the metal precursor of Formula 5 may react with the surface functional group of the organic molecular layer (that is, OM) previously formed, and thus, may be self-assembled on the surface of the organic molecular layer (that is, OM). During this process, Rₐ₂R_{b1} may be generated as a reaction by-product. In addition, *—X_{c}Rₐ₃ is a side functional group of the organic molecular layer (that is, OM) in another adjacent molecular line, and the metal precursor of Formula 5 may react with the side functional group of the organic molecular layer (that is, OM) previously formed. Reaction Formula 2 shown above corresponds to the case where nb in Formula 5 is 1. During this process, Rₐ₃L_{b} may be generated as a reaction by-product.

Next, in the purge operation, the remaining metal precursor and the reaction by-products may be purged. In Reaction Formula 2, the respective functional groups may be the same as defined in Formulae 4 and 5.

In the metal precursor dosing operation, while a metal precursor control valve 130 is opened and the gas outlet valve 142 is closed, a metal precursor gas may be supplied from the metal precursor storage unit 110 to the inside of the chamber 100 (a metal precursor supply operation). The metal precursor may be stored in a solid state, a liquid state, or a gaseous state in the metal precursor storage unit 110. The metal precursor storage unit 110 may be heated to a temperature less than the thermal-decomposition temperature of the metal precursor, and thus, the metal precursor may be supplied at a certain vapor pressure into the chamber 100. Here, the metal precursor may be supplied without a carrier gas. In other words, the metal precursor alone may be supplied into the chamber 100.

Because the metal precursor is supplied while the gas outlet valve 142 is closed, the metal precursor may be accumulated in the chamber 100 to increase the pressure in the chamber 100. The metal precursor may be supplied such that the pressure of the chamber 100 reaches a reaction pressure (the metal precursor supply operation). Here, the reaction pressure is a pressure of the metal precursor alone in the chamber 100 and may be tens of mTorr to 10 Torr, specifically, 50 mTorr to 10 Torr, 100 mTorr to 6 Torr, 600 mTorr to 5 Torr, or 700 mTorr to 2 Torr. In general, a precursor is dosed together with a carrier gas into a chamber, and in this case, considering that the partial pressure of the precursor is about 1 mTorr, the case where the pressure of the metal precursor alone in the chamber 100 is 50 mTorr or more may mean that the metal precursor is pressurized.

When the pressure of the chamber 100 reaches the reaction pressure, the metal precursor control valve 130 may be closed, and the chamber may be sealed for a certain period of time (a metal precursor exposure operation). The metal precursor supply operation and the metal precursor exposure operation may be referred to as the metal precursor dosing operation. However, the metal precursor exposure operation may be omitted in some cases. In the metal precursor dosing operation, the reaction according to Reaction Formula 2 may occur.

Next, the chamber 100 may be purged (a metal precursor purge operation). Specifically, the purge gas in the purge gas storage unit 112 may flow onto the surface of the substrate by opening the purge gas control valve 132 and the gas outlet valve 142, thereby removing the excess metal precursor, which is not adsorbed onto the substrate of the substrate, and the reaction by-products. Here, the purge gas is an inert gas, and the inert gas may include, for example, argon (Ar), nitrogen (N₂), or a combination thereof.

Unlike the illustrated example, when the inorganic monomolecular layer (that is, MM) is formed in a plurality of layers (when n in Formula 1 is 2 or more), after the metal precursor dosing operation according to Reaction Formula 2 and the purge operation, which are described above, are performed, a unit cycle, which includes a reaction gas dosing operation for dosing a reaction gas and thus reacting the reaction gas with the metal precursor chemically bonded to the lower layer, a purge operation for purging the unreacted reaction gas and a reaction product by supplying the purge gas, the metal precursor dosing operation, and the purge operation, may be repeated n−1 times. Here, the reaction gas may include hydrogen, an oxygen-containing gas (for example, O₂, O₃, H₂O), a nitrogen-containing gas (for example, NH₃), or the like.

The control unit may control the opening and closing of the valves and the temperature of the chamber.

As such, the reaction as in Reaction Formula 1 may be performed in a pressurized environment in which the pressure of the organic precursor alone is 50 mTorr or more, specifically, 100 mTorr or more. In this case, the organic precursor may undergo the reaction so as to be densely arranged on the substrate, and thus, the main chain of the organic precursor may be arranged in an upward direction, for example, a vertical direction, with respect to the substrate 10. In addition, the reaction as in Reaction Formula 1 may be performed in a state in which the gas outlet valve 142 is closed, specifically, in a pressurized stagnant environment rather than a laminar flow environment. In this case, the reaction for the organic precursor to be densely arranged on the substrate may be more efficiently performed. However, the present disclosure is not limited thereto, and the organic precursor may be supplied alone without a carrier gas while the gas outlet valve 142 is opened, and thus, may undergo the reaction while laminar flow is formed in the chamber.

A molecular layer deposition device according to an embodiment of the present disclosure may perform a cycle, which includes forming an inorganic monomolecular layer (that is, MM in Formula 1) and forming an organic molecular layer (that is, OM in Formula 1), a plurality of times, specifically, as many times as indicated by I in Formula 1.

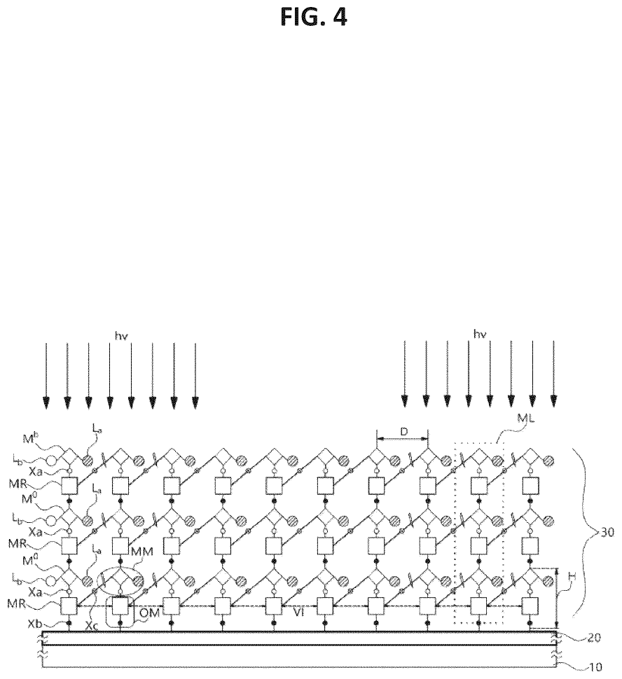

FIGS. 4 to 7 are schematic diagrams sequentially illustrating a photolithography method according to an embodiment of the present disclosure. For convenience of description, FIGS. 4 to 7 illustrate an example in which the multilayer molecular film photoresist 30 corresponds to the case where all of n, m, and l in FIG. 1 are 1, wherein, in Formula 3 representing the organic monomolecule, all Z₃, Z₄, and Z₅ are direct bonds, n is 1, and m is 0, and wherein, in Formula 2 representing the inorganic monomolecule, both Z₁ and Z₂ are direct bonds, and both na and nb are 1.

Referring again to FIG. 3, the substrate 10, on which the etch-target layer 20 is formed, may be provided. The substrate 10 and the etch-target layer 20 may be same as described with reference to FIG. 1. The multilayer molecular film photoresist 30 may be formed on the etch-target layer 20. In the multilayer molecular film photoresist 30, there may be a cross-link corresponding to MR-X_{c}-M⁰ between adjacent molecular lines, as described with reference to Reaction Formula 2.

Referring to FIG. 4, a portion of the multilayer molecular film photoresist 30 may be irradiated with radiation (that is, hv), specifically, EUV or an e-beam. In this case, the X_{c}-M⁰ bond between adjacent molecular lines in the photoresist 30 may be broken. This is because M⁰ is Te that is extremely stable, the X_{c}—Te bond may be easily broken by the radiation, and after the X_{c}—Te bond is broken, Te may be stably maintained without reacting with any other functional group. The breaking of the X_{c}—Te bond may be due to secondary electrons generated by Te when Te absorbs the radiation according to the irradiation of EUV or the e-beam.

However, the X_{c}-M⁰ bond in a region not irradiated with the radiation (that is, hv) may be maintained.

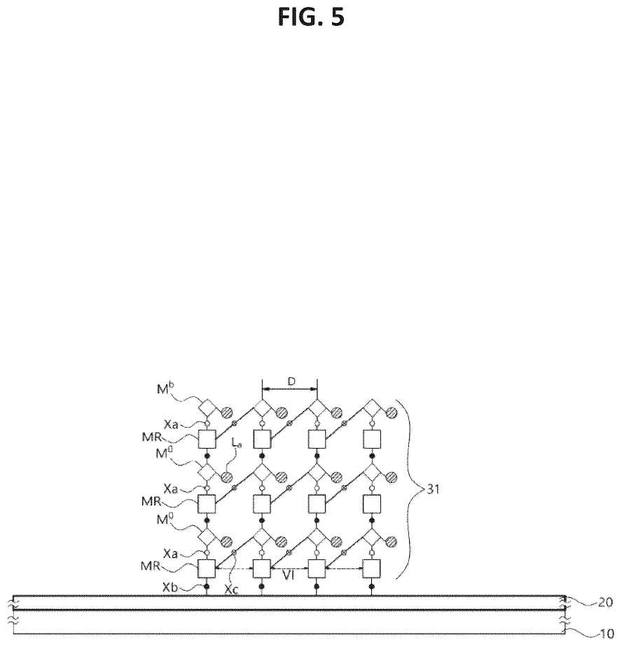

Referring to FIG. 5, the multilayer molecular film photoresist 30 exposed to the radiation may be exposed to a developer. In this case, portions of the multilayer molecular film photoresist 30 except for the portion in which the X_{c}-M⁰ bond in adjacent molecular lines (that is, ML) is maintained may be removed by the developer, thereby forming a multilayer molecular film photoresist pattern 31. The developer may include a developing solution, for example, water, isopropyl alcohol (IPA), methyl isobutyl ketone (MIBK), or tetramethylammonium hydroxide (TMAH), a developing gas, for example, CF₄, Ar, O₂, CHF₃, or the like, or plasma generated therefrom.

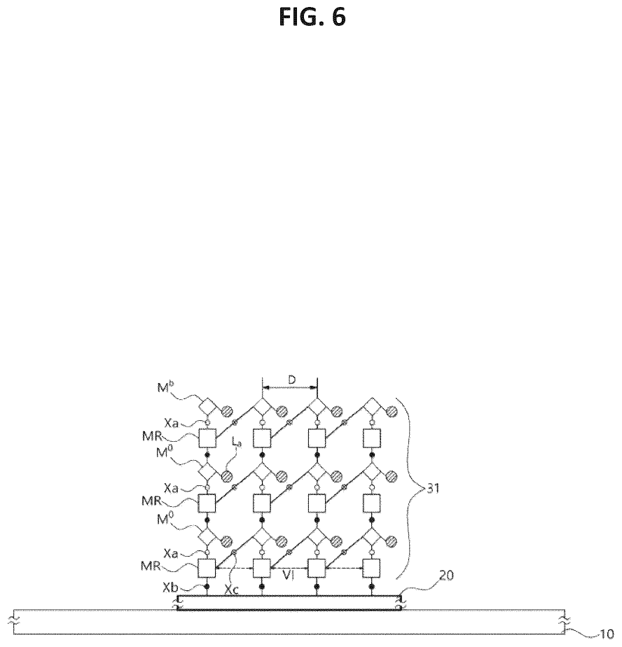

Referring to FIG. 6, the etch-target film 20 may be etched by using the multilayer molecular film photoresist pattern 31 as a mask. This etching may include, for example, plasma etching.

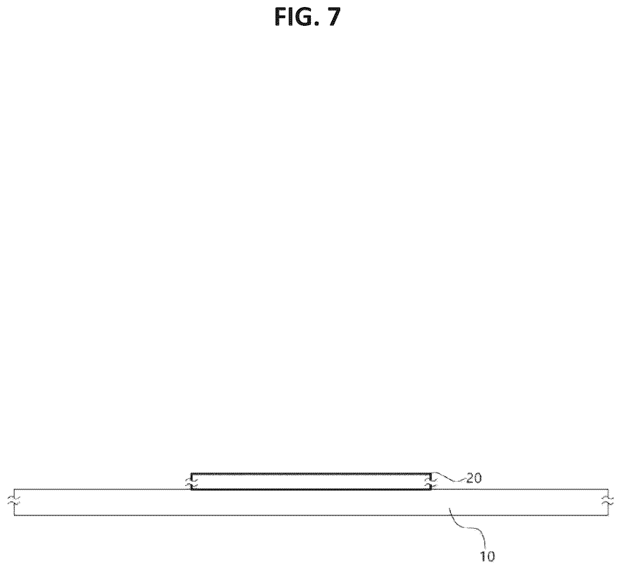

Referring to FIG. 7, the multilayer molecular film photoresist pattern 31 may be removed. This removal may be performed by an ashing method.

As described above, according to the multilayer molecular film photoresist 30, as inorganic monomolecules and organic monomolecules, which are connected to each other in the molecular lines by bonds, are formed by self-assembly, the respective molecular lines may be grown in the upward direction with respect to the substrate without being intertwined with each other or being slantly grown, and the molecular lines may be uniformly arranged in the horizontal direction. The molecular lines may be densely formed enough for organic monomolecules in adjacent molecular lines to have a Van der Waals interaction (that is, VI) therebetween. Here, the Van der Waals interaction may stabilize the molecular lines adjacent to each other in the horizontal direction, and thus, may allow patterns not to collapse even when the patterns have high aspect ratios. As such, the reason of the dense formation of the molecular lines may be because the pressure of the organic precursor and/or the metal precursor in the chamber is increased by performing the dosing of the organic precursor and/or the metal precursor without using a carrier gas. To this end, the dosing of the organic precursor and/or the metal precursor may be performed while the gas outlet port of the chamber is closed. In this case, the height (that is, H in FIG. 2) of a —[X_{b}-MR-Xₐ-M⁰]- or [X_{b}—Z₃-MR-Z₄—Xₐ—Z₁-M⁰-Z₂—]- unit layer may be almost equal to the length of the unit layer, which reflects actual sizes of atoms in the unit layer and actual lengths of bonds between the atoms.

As such, the interval (that is, D in FIG. 2) between the molecular lines may be 1 nm or less, specifically, 0.5 nm or less, which is extremely small. In addition, as separation between the molecular lines instead of particles occurs during light-exposure and development, line edge roughness (LER), which refers to pattern side roughness, may be extremely low, for example, 1.2 nm or less, and resolution may also significantly improve to be, for example, 6 nm or less. In addition, the multilayer molecular film photoresist 30 may have low stochastic failure and high photosensitivity (for example, 10 mJ/cm²).

Furthermore, the multilayer molecular film photoresist 30 of the present disclosure may allow a bond in a light-irradiated region thereof to be broken, thereby implementing a positive-type photoresist pattern.

Hereinafter, examples are described to help for a better understanding of the present disclosure. However, the following examples are provided only to help for a better understanding of the present disclosure, and the present disclosure is not limited to the following examples.

### Preparation Example: Preparation Example of Photoresist

A substrate was loaded into a chamber including a gas inlet port and a gas outlet port, and the temperature of the substrate was heated to 100° C.

While the gas outlet port was closed, 2,3-dimercaptopropanol (DMP) was supplied as an organic precursor onto the substrate through the gas inlet port without a carrier gas such that the pressure in the chamber reached 50 mTorr (an organic precursor supply operation). Next, while the chamber pressure was maintained at 50 mTorr by closing the chamber inlet port, the organic precursor was caused to react with the substrate for 1 second (an organic precursor exposure operation). Next, while both the gas inlet port and the gas outlet port were opened, argon, which is a purge gas, was supplied to the gas inlet port for 800 seconds, thereby purging a reaction by-product and a residual reaction gas (an organic precursor purge operation). The organic precursor supply operation, the organic precursor exposure operation, and the organic precursor purge operation constitute an organic precursor sub-cycle.

Next, while the gas outlet port was closed, Te(OEt)₄, which is a Te precursor, was supplied as a metal precursor onto the organic precursor layer through the gas inlet port without a carrier gas such that the pressure in the chamber reached 50 mTorr (a metal precursor supply operation). Next, while the chamber pressure was maintained at 50 mTorr by closing the chamber inlet port, the metal precursor was caused to react with the surface of the organic precursor for 5 seconds (a metal precursor exposure operation). Next, while both the gas inlet port and the gas outlet port were opened, argon, which is a purge gas, was supplied to the gas inlet port for 800 seconds, thereby purging a reaction by-product and a residual reaction gas (a metal precursor purge operation). The metal precursor supply operation, the metal precursor exposure operation, and the metal precursor purge operation constitute a metal precursor sub-cycle.

A unit cycle including one metal precursor sub-cycle and one organic precursor sub-cycle was performed 40 times, thereby forming a multilayer molecular film photoresist having a thickness of about 20 nm.

Here, a growth rate was 5 Å/cycle. This is similar to the length of a unit reaction product obtained by reaction between one molecule of the Te precursor and one molecule of the organic precursor, which were used. From this result, when the unit cycle is performed in preparing the photoresist according to the Preparation Example, a main chain (or a molecular line) of the reaction product obtained by reaction between the Te precursor and the organic precursor on the substrate may be supposed to be grown in the upward direction, specifically, in a substantially vertically upward direction, with respect to the substrate without lying down on the substrate or being inclined. This may mean that, because the distance between the respective organic monomolecules in the molecular lines is small enough to have a Van der Waals interaction, even when the thickness of the photoresist is increased, the growth of the molecular line in the substantially vertically upward direction may be maintained due to the Van der Waals interaction without the collapse of the molecular line.

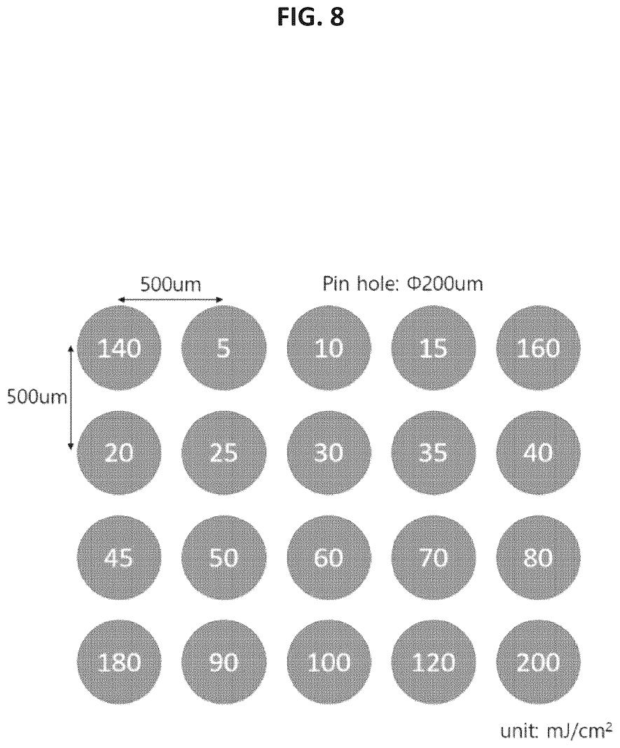

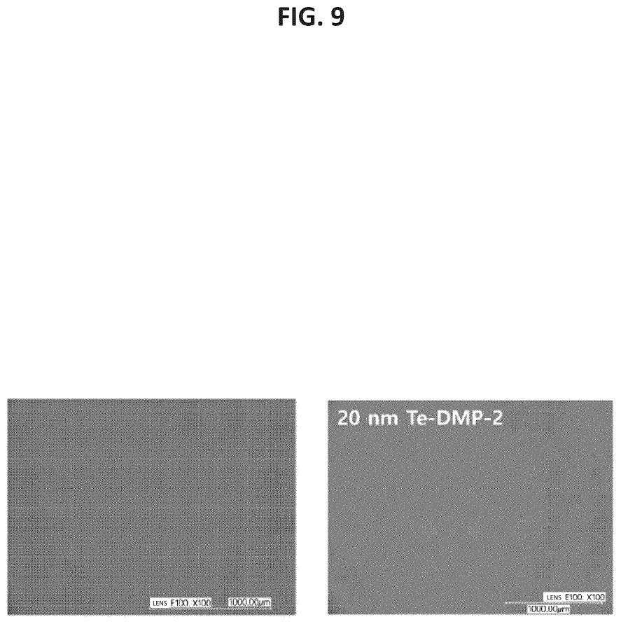

FIG. 8 is a schematic diagram illustrating a EUV irradiation form and a dose condition, and FIG. 9 shows optical photographs of photoresist patterns obtained after an EUV pattern shown in FIG. 8 is irradiated onto the photoresist according to the Preparation Example. Specifically, FIG. 9 shows photographs of photoresist patterns obtained by performing exposure through the irradiation of the photoresist according to the Preparation Example with the EUV pattern shown in FIG. 8, followed by performing development through ultrasonic treatment in 2.39 wt % TMAH in H₂O for 8 minutes and then performing rinse in deionized water for 10 seconds.

Referring to FIGS. 8 and 9, when the photoresist according to the Preparation Example is exposed to EUV, it may be seen that, as a pattern of an exposed region thereof is removed and a pattern of a non-exposed region thereof remains, holes obtained by removing the exposed region are generated. When the photoresist is exposed at a dose of about 60 mJ/cm² or more and then developed, the photoresist has a thickness of about 12 nm. From this result, it may be seen that the EUV sensitivity of the photoresist according to the Preparation Example is 60 mJ/cm².

1. A multilayer molecular film photoresist comprising:
a plurality of molecular lines arranged in a horizontal direction and each extending in an upward direction with respect to a substrate, each molecular line comprising monomolecules linearly connected to each other, and the monomolecules comprising multiple inorganic monomolecules comprising metal atoms and an organic monomolecule connected between at least some inorganic monomolecules from among the inorganic monomolecules,
wherein the organic monomolecule included in one of the molecular lines is cross-linked with an inorganic monomolecule in another adjacent molecular line, and
the cross-linking is broken by irradiation of radiation.

2. The multilayer molecular film photoresist of claim 1, wherein the metal atoms included in the inorganic monomolecules are Te.

3. The multilayer molecular film photoresist of claim 1, wherein the inorganic monomolecules and the organic monomolecule, which are located within the molecular lines, are connected to each other by a bond that is included in one thereof and selected from the group consisting of —O—, —S—, —Se—, —NR— (where R is H or CH₃) and —PR— (where R is H or CH₃).

4. The multilayer molecular film photoresist of claim 1, wherein the organic monomolecule comprises, as a body, an aromatic or non-aromatic ring or a linear or branched alkylene group, —Z₅X_{c}—*′ being bonded to a side portion of the body, wherein Z₅ is a direct bond or a C1 to C5 substituted or unsubstituted and linear or branched alkylene group, X_{c} is O, S, Se, NR (where R is H or CH₃), or PR (where R is H or CH₃), and *′ is a cross-link with an inorganic monomolecule in another adjacent molecular line.

5. The multilayer molecular film photoresist of claim 1, wherein the organic monomolecule is represented by Formula 3: 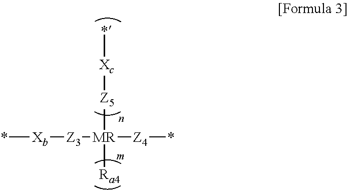
wherein, in Formula 3, MR, which is a body of the organic monomolecule, is an aromatic or non-aromatic ring or a linear or branched alkylene group, one of the * is a bond with a lower inorganic monomolecule in the same molecular line, the other * is a bond with an upper inorganic monomolecule in the same molecular line, *′ is a cross-link with an inorganic monomolecule in another adjacent molecular line,
X_{b} and X_{c} are each independently O, S, Se, NR (where R is H or CH₃) or PR (where R is H or CH₃),
Z₃, Z₄, and Z₅ are each independently a direct bond or a C1 to C5 substituted or unsubstituted and linear or branched alkylene group,
Rₐ₄ is hydrogen or a C1 to C2 alkyl group,
n is 1 to 2, and m is 0 to 1.

6. The multilayer molecular film photoresist of claim 5, wherein MR is a C2 to C6 linear alkylene group,
Z₃, Z₄, and Z₅ are direct bonds,
X_{b} is O, X_{c} is S,
n is 1, and m is 0.

7. The multilayer molecular film photoresist of claim 1, wherein the inorganic monomolecules are represented by Formula 2:
[Formula 2] 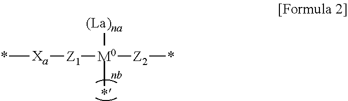
wherein, in Formula 2, one of the * is a bond with a lower inorganic monomolecule in the same molecular line, the other * is a bond with an upper inorganic monomolecule in the same molecular line, *′ is a cross-link with an inorganic monomolecule in another adjacent molecular line,
M⁰ is Te,
Xₐ is O, S, Se, NR (where R is H or CH₃) or PR (where R is H or CH₃),
Z₁ and Z₂ are each independently a direct bond, a C1 to C20 substituted or unsubstituted linear or branched alkylene group, a C1 to C20 substituted or unsubstituted linear or branched alkyleneoxide, a C1 to C20 substituted or unsubstituted linear or branched alkyleneamino, a C1 to C20 substituted or unsubstituted linear or branched alkylenesilylamino, a C1 to C20 substituted or unsubstituted linear or branched alkylenethio, a C1 to C20 substituted or unsubstituted linear or branched alkyleneseleno, or a C1 to C20 substituted or unsubstituted linear or branched alkylenephosphino,
Lₐ is a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group,
na is an integer of 0 to 3, and
nb is an integer of 1 to 2.

8. The multilayer molecular film photoresist of claim 7, wherein Xₐ is S,
Z₁ and Z₂ are direct bonds, and
nb is 1.

9. The multilayer molecular film photoresist of claim 1, wherein the radiation is an e-beam or EUV.

10. The multilayer molecular film photoresist of claim 1, wherein there is a Van der Waals interaction between the organic monomolecules within molecular lines adjacent to each other in the horizontal direction.

11. A method of fabricating a photoresist pattern, the method comprising:
providing a multilayer molecular film photoresist that comprises a plurality of molecular lines arranged in a horizontal direction and each extending in an upward direction with respect to a substrate, wherein each molecular line comprises monomolecules linearly connected to each other, the monomolecules comprise multiple inorganic monomolecules comprising metal atoms and an organic monomolecule connected between at least some inorganic monomolecules from among the inorganic monomolecules, and the organic monomolecule included in one of the molecular lines is cross-linked with an inorganic monomolecule in another adjacent molecular line;
irradiating a region of the multilayer molecular film photoresist with radiation that is an e-beam or EUV, wherein the cross-linking in the region irradiated with the radiation gets broken; and
removing the region, which is exposed to the radiation, of the multilayer molecular film photoresist, by development.
